(19) United States
(12) Patent Application Publication
(10) Pub. No.: US 2024/0242048 A1
(43) Pub. Date: Jul. 18, 2024

(54) DROPLET PROCESSING DEVICE AND DROPLET PROCESSING METHOD

(71) Applicant: SEMES CO., LTD., Cheonan-si (KR)

(72) Inventor: Sang Hyun PARK, Busan (KR)

(73) Assignee: SEMES CO., LTD., Cheonan-si (KR)

(21) Appl. No.: 18/404,186

(22) Filed: Jan. 4, 2024

(30) Foreign Application Priority Data
Jan. 13, 2023 (KR) 10-2023-0005292

(51) Int. Cl. G06K 15/02; G06K 15/10

(52) U.S. Cl. CPC G06K 15/1881; G06K 15/102; G06K 15/1843

(57) ABSTRACT

Provided are a droplet processing device and a droplet processing method which may increase a thickness of a targeted area to be greater than a thickness of an untargeted area in a process of forming a thin film by using a dot pattern of ink. The droplet processing device includes: a droplet profile generating terminal for generating a general area halftoning image to which a random print pattern is applied, generating a target area halftoning image to which the random print pattern is not applied, and synthesizing the general area halftoning image and the target area halftoning image to generate a synthesized image; and an inkjet system for receiving an input of the synthesized image and spraying droplets onto a substrate based on dot locations present in the synthesized image.

### CROSS-REFERENCE TO RELATED APPLICATIONS

This application claims priority to and the benefit of Korean Patent Application No. 10-2023-0005292 filed in the Korean Intellectual Property Office on Jan. 13, 2023 the entire contents of which are incorporated herein by reference.

### TECHNICAL FIELD

The present invention relates to a droplet processing device and a droplet processing method, and more particularly to a droplet processing device and a droplet processing method for printing ink on a substrate.

### BACKGROUND ART

The method of manufacturing display substrates, photovoltaic substrates, and semiconductor substrates using inkjet has the advantage that a pattern layer can be formed without conventional processes, such as deposition, exposure, and development, by simply performing printing with ink, so that in terms of manufacturing cost, it has the advantage of being able to manufacture a substrate at a relatively lower cost than other substrate manufacturing methods.

In the method of manufacturing a substrate by using inkjet, printing is performed for the purpose of forming an organic layer, an insulating layer, a conductive layer, or an encapsulation layer in the form of a pattern on a substrate having an element formed on an upper surface of a glass.

In this case, the substrate is not printed with a single cell for a single product, but rather a plurality of cells is formed on a substrate, and a process of sawing each of the plurality of cells is applied after the end of the process to make a product.

In this case, each of the cells formed on the substrate is subjected to a printing process using ink, for example, in the process of forming a sealing layer on a display substrate, the substrate may be divided into an active area where pixels are displayed and an edge area that is inserted into a monitor cover side.

The active area and the edge area formed on the display substrate in the related art are printed with a uniform thickness targeted by the dot pattern during printing. In order to form the dot patterns with the targeted uniform thickness, a random print pattern is usually used to prevent agglomeration phenomenon in which the dots of the dot patterns agglomerate.

The random print pattern is a preset pattern that distributes the dots so that the prescribed number of dots per unit plane is located at the time of printing. When the random print pattern is printed on a substrate, in single printing, all nozzles do not discharge ink, rather some nozzles selectively discharge ink, among the nozzles discharging ink.

Therefore, when printing progresses the random print pattern, a significantly smaller amount of ink may be discharged because not all the nozzles discharge ink, but only some of the nozzles discharge ink. As a result, there is a limitation that the thickness of a thin film cannot be increased by more than a certain amount when forming the thin film with the random print pattern.

Currently, when a thin film is formed with a random print pattern, the nozzles can only discharge up to 50% of the total amount of ink discharged, so that the thickness of the thin film formed is only a thickness corresponding to 50% of the total amount of ink discharged.

In addition, when the active area and the edge area are printed by using a random print pattern with the limitations described above, the dots are attracted to each other by surface tension. In this case, the surface tension is highest toward the center of the active area and decreases toward the outer side of the edge area.

As a result, in the edge area, the printed dots agglomerate together toward the center of the active area due to the surface tension as described above, and an unfilled area where no dots remain is generated around the area where the dots agglomerate.

To prevent the unfilled area from being generated, it may consider to make the thickness of the edge area higher than the active area so that the ink printed on the edge area is not attracted to the active area by surface tension.

However, as mentioned above, the thickness of the film that can be increased is very limited when a random print pattern is inevitably used, and a technical solution is needed to increase the thickness of the thin film in a specific area.

### SUMMARY OF THE INVENTION

A technical object of the present invention to solve the foregoing problems is to provide a droplet processing device and a droplet processing method which may increase a thickness of a targeted area to be greater than a thickness of an untargeted area in a process of forming a thin film by using a dot pattern of ink.

Another technical object of the present invention to solve the foregoing problems is to provide a droplet processing device and a droplet processing method which, in a process of forming a thin film by using a dot pattern of ink, increase a thickness of the thin film beyond a limit by preventing a random print pattern from being applied to an outer side of an area to which the random print pattern is applied, thereby preventing an unfilled area of ink from being generated around the edge area.

Another technical object of the present invention to solve the foregoing problems is to provide a droplet processing device and a droplet processing method which may increase a thickness of a thin film by discharging up to 100% of the total amount of ink discharged of an inkjet system, beyond the limitation of only using 50% of the total amount of ink discharged of the entire inkjet system when a random print pattern is used on a substrate.

The object of the present invention is not limited thereto, and other objects not mentioned will be clearly understood by those of ordinary skill in the art from the following description.

An exemplary embodiment of the present invention provides a droplet processing device including: a droplet profile generating terminal for generating a general area halftoning image to which a random print pattern is applied, generating a target area halftoning image to which the random print pattern is not applied, and synthesizing the general area halftoning image and the target area halftoning image to generate a synthesized image; and an inkjet system for receiving an input of the synthesized image and spraying droplets onto a substrate based on dot locations present in the synthesized image.

According to the exemplary embodiment, the droplet profile generating terminal may include: a general area size setting unit which sets the general area size information for a general area; and a general area brightness setting unit which receives an input of the general area size information in conjunction with the general area size setting unit and sets general area brightness information for the general area size information.

According to the exemplary embodiment, the general area brightness setting unit may set the general area brightness information to gray scale.

According to the exemplary embodiment, the droplet profile generating terminal may further include a general area resolution setting unit which receives an input of the general area brightness information from the general area brightness setting unit, and sets general area resolution information for the general area size information to generate a pixelated general area image.

According to the exemplary embodiment, the droplet profile generating terminal may further include a general area halftoning setting unit which receives an input of the general area image in conjunction with the general area resolution setting unit, and halftones the general area image in the form of dots to generate a general area halftoning image.

According to the exemplary embodiment, the droplet profile generating terminal may further include a random print setting unit which receives an input of the general area halftoning image in conjunction with the general area halftoning setting unit, and randomly distributes at least one portion of the general area halftoning image in the form of dots to form a general area random print image.

According to the exemplary embodiment, the droplet profile generating terminal may further include a target area size setting unit which sets the target area size information for a target area.

According to the exemplary embodiment, the target area size setting unit may set the target area to surround a border of the general area.

According to the exemplary embodiment, the droplet profile generating terminal may further include a target area brightness setting unit which receives an input of the target area size information in conjunction with the target area size setting unit, and sets target area brightness information for the target area size information.

According to the exemplary embodiment, the target area brightness setting unit may set the target area brightness information to gray scale.

According to the exemplary embodiment, the target area brightness setting unit may form the target area brightness information to brightness lower than the general area brightness information.

According to the exemplary embodiment, the droplet profile generating terminal may further include a target area resolution setting unit which receives an input of the target area brightness information from the target area brightness setting unit, and sets target area resolution information for the target area size information to generate a pixelated target area image.

According to the exemplary embodiment, the droplet profile generating terminal may further include a target area halftoning setting unit which receives an input of the target area image in conjunction with the target area resolution setting unit, and generates a target area halftoning image by halftoning the target area image in the form of dots.

According to the exemplary embodiment, the droplet profile generating terminal may further include a synthesized image generating unit which receives an input of the general area halftoning image from the general area halftoning setting unit, receives an input of the target area halftoning image from the target area halftoning setting unit, and formats the general area halftoning image and the target area halftoning image into a single image to generate a synthesized image.

According to the exemplary embodiment, the droplet profile generating terminal may further include a synthesized image transmitting unit which receives an input of the synthesized image in conjunction with the synthesized image generating unit, and transmits the received synthesized image to an inkjet system.

Another exemplary embodiment of the present invention provides a droplet processing method including: a size information setting operation of setting general area size information for a general area and target area size information for a target area; a brightness information setting operation of setting general area brightness information for the general area size information and setting target area brightness information for the target area size information; a rasterization operation of generating a pixelated general area image by setting general area resolution information for the general area size information, and generating a pixelated target area image by setting target area resolution information for the target area size information; a halftoning operation of halftoning the general area image in the form of dots to generate a general area halftoning image, and halftoning the target area image in the form of dots to generate a target area halftoning image; a synthesizing operation of formatting the general area halftoning image and the target area halftoning image into a single image to generate a synthesized image; and a printing operation of supplying the synthesized image to an inkjet system to make the synthesized image be printed on a substrate.

According to the exemplary embodiment, in the brightness information setting operation, the brightness information may be set to gray scale, and the target area brightness information may be set to be brightness lower than the general area brightness information.

According to the exemplary embodiment, the droplet processing method may further include, between the halftoning operation and the synthesizing operation, a random print pattern forming operation of randomly distributing at least a portion of the general area halftoning image in the form of dots.

According to the exemplary embodiment, in the size information setting operation, the target area may be set to surround a border of the general area.

Still another exemplary embodiment of the present invention provides a droplet processing device including: a droplet profile generating terminal including a general area size setting unit which sets general area size information for a general area, a general area brightness setting unit which receives an input of the general area size information in conjunction with the general area size setting unit, sets general area brightness information for the general area size information, and sets the general area brightness information to gray scale, a general area resolution setting unit which receives an input of the general area brightness information from the general area brightness setting unit, and sets general area resolution information for the general area size information to generate a pixelated general area image, a general area halftoning setting unit which receives an input of the general area image in conjunction with the general area resolution setting unit, and halftones the general area image in the form of dots to generate a general area halftoning image, a random print setting unit which receives an input of the general area halftoning image in conjunction with the general area halftoning setting unit, and randomly distributes at least one portion of the general area halftoning image in the form of dots to form a general area random print image, a target area size setting unit which sets the target area size information for a target area and sets the target area to surround a border of the general area, a target area brightness setting unit which receives an input of the target area size information in conjunction with the target area size setting unit, sets target area brightness information for the target area size information to lower brightness than the general area brightness information, and sets the target area brightness information to gray scale, a target area resolution setting unit which receives an input of the target area brightness information from the target area brightness setting unit, and sets target area resolution information for the target area size information to generate a pixelated target area image, a target area halftoning setting unit which receives an input of the target area image in conjunction with the target area resolution setting unit, and generates a target area halftoning image by halftoning the target area image in the form of dots, a synthesized image generating unit which receives an input of the general area halftoning image from the general area halftoning setting unit, receives an input of the target area halftoning image from the target area halftoning setting unit, and formats the general area halftoning image and the target area halftoning image into a single image to generate a synthesized image, and a synthesized image transmitting unit which receives an input of the synthesized image in conjunction with the synthesized image generating unit, and transmits the received synthesized image to an inkjet system; and an inkjet system for receiving an input of the synthesized image and spraying droplets onto a substrate based on dot locations present in the synthesized image.

The present invention has an effect of increasing a thickness of a targeted area to be greater than a thickness of an untargeted area in a process of forming a thin film by using a dot pattern of ink.

Further, the present invention has an effect of, in a process of forming a thin film by using a dot pattern of ink, increasing a thickness of the thin film beyond a limit by preventing a random print pattern from being applied to an outer side of an area to which the random print pattern is applied, thereby preventing an unfilled area of ink from being generated.

Furthermore, the present invention has an effect of increasing a thickness of a thin film by discharging up to 100% of the total amount of ink discharged of an inkjet system, beyond the limitation of only using 50% of the total amount of ink discharged of the entire inkjet system by a random print pattern.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram of a droplet processing device according to an exemplary embodiment of the present invention.

FIG. 2 is a block diagram of a droplet profile generating terminal illustrated in FIG. 1.

FIG. 3 is a diagram illustrating an example of a state in which a size of a general area illustrated in FIG. 2 is displayed on the droplet profile generating terminal.

FIG. 4 is a diagram illustrating an example of a state in which brightness information is formed for each of the general areas illustrated in FIG. 3.

FIG. 5 is a diagram illustrating an example of a state in which resolution information is formed for each of the general areas illustrated in FIG. 4.

FIG. 6 is a diagram illustrating an example of halftoning each of the general areas illustrated in FIG. 5.

FIG. 7 is a diagram illustrating an example of a state in which the general area halftoning image illustrated in FIG. 6 is randomly distributed in the form of dots to form a general area random print image.

FIG. 8 is an example of a state in which a size of a target area illustrated in FIG. 2 is displayed on the droplet profile generating terminal.

FIG. 9 is a diagram illustrating a state in which brightness information is formed for each of the target areas illustrated in FIG. 8.

FIG. 10 is a diagram illustrating an example of a state in which resolution information is formed for each of the target areas illustrated in FIG. 9.

FIG. 11 is a diagram illustrating an example of a state in which each of the target areas illustrated in FIG. 10 is halftoned.

FIG. 12 is a diagram illustrating an example of a synthesized image of the general area halftoning image illustrated in FIG. 6 and the target area halftoning image illustrated in FIG. 11.

FIG. 13 is a graph representing the distance between the target area and the general area as the x-axis and representing the thickness of the ink as the y-axis when printing is performed with the synthesized image illustrated in FIG. 12.

FIG. 14 is a flowchart of a droplet processing method according to an exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

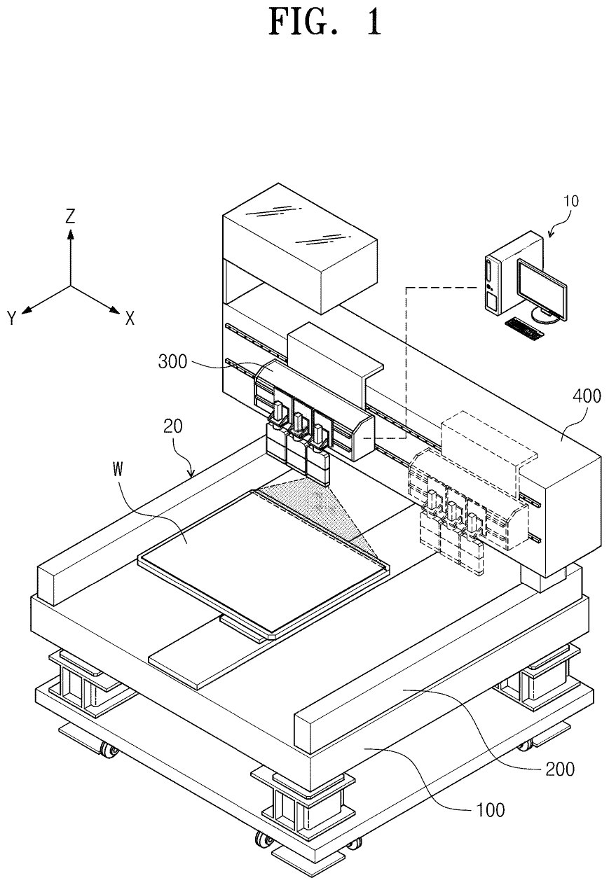

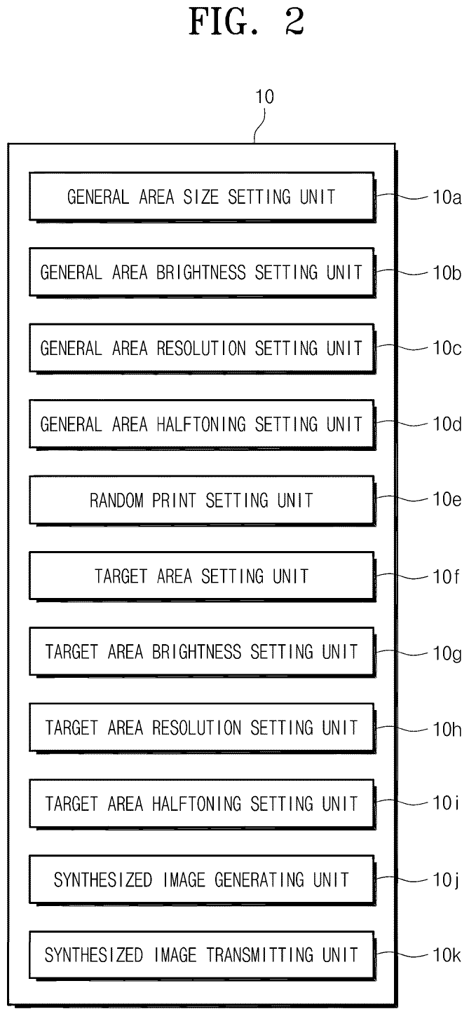

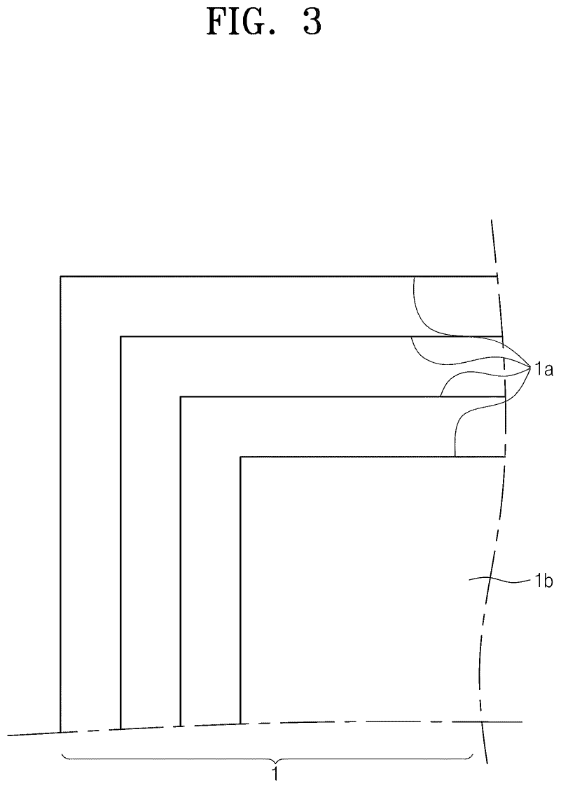

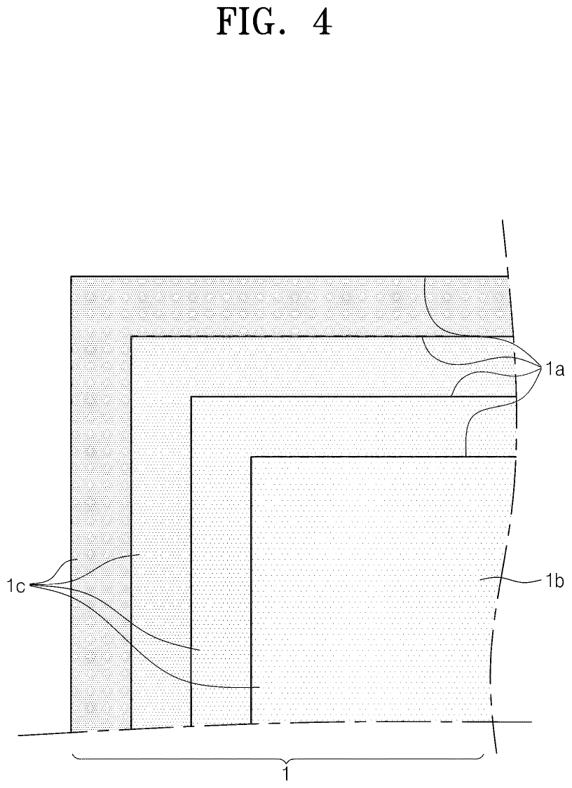

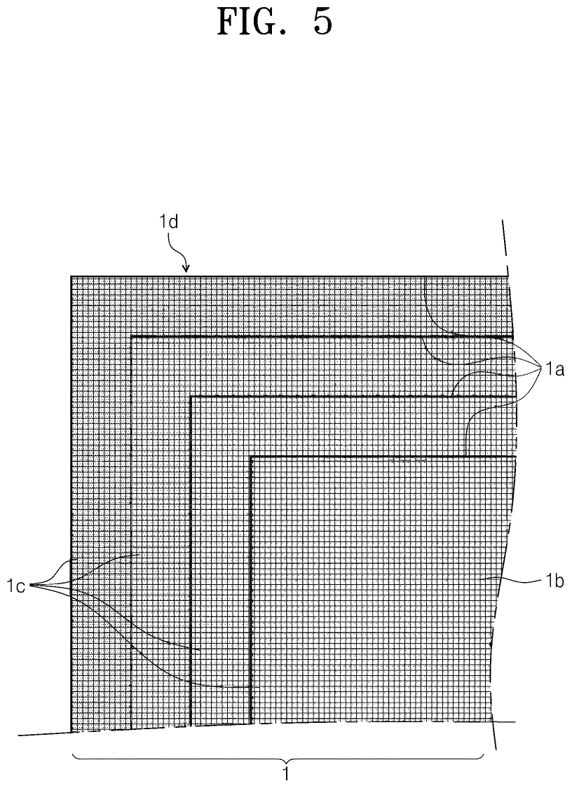

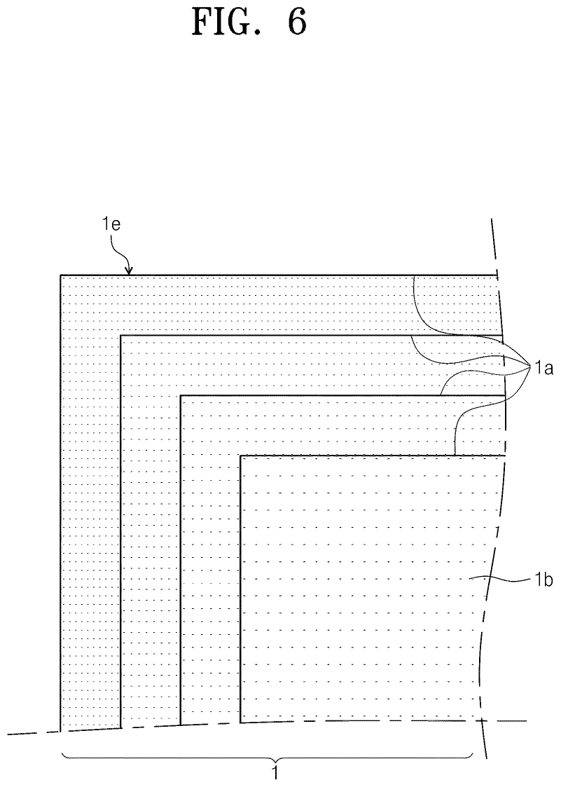

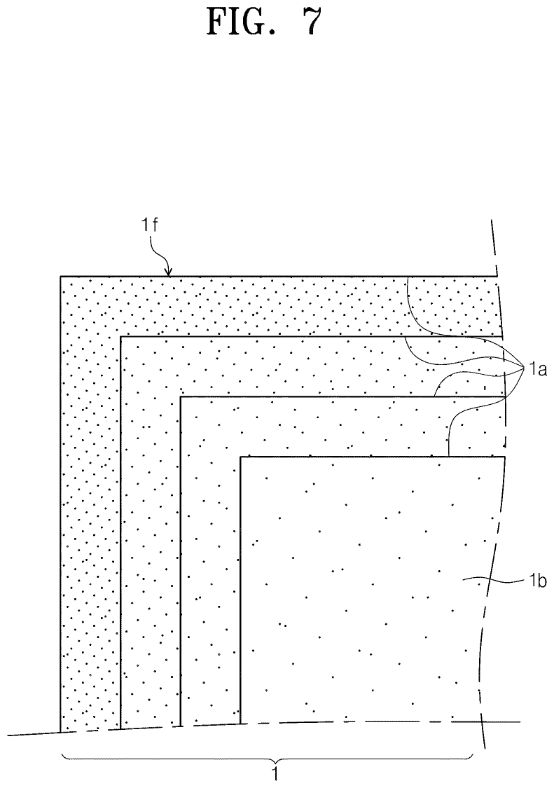

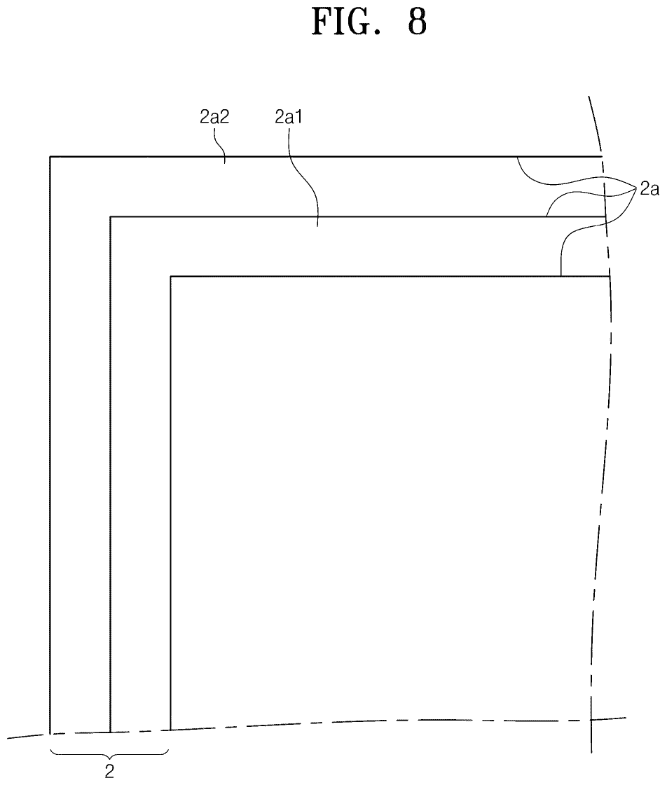

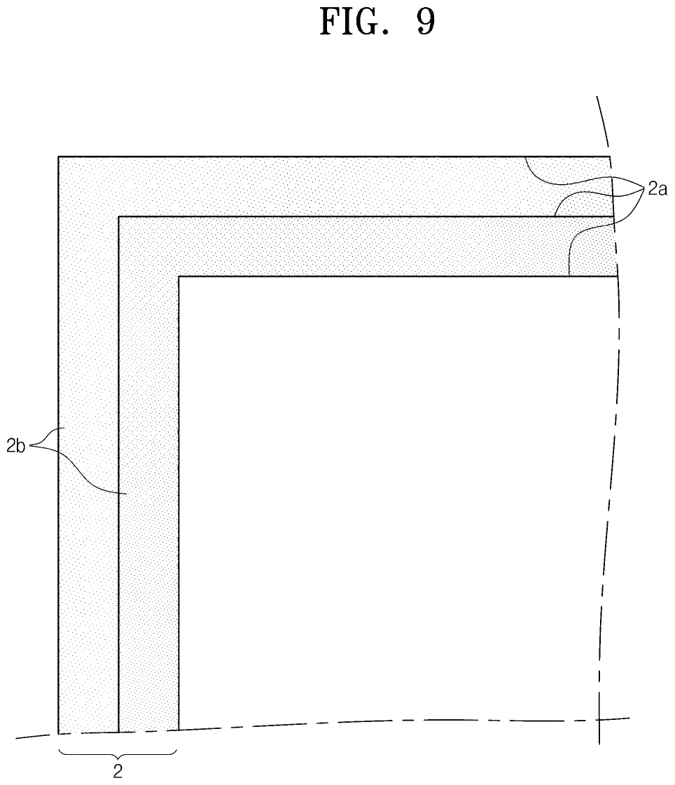

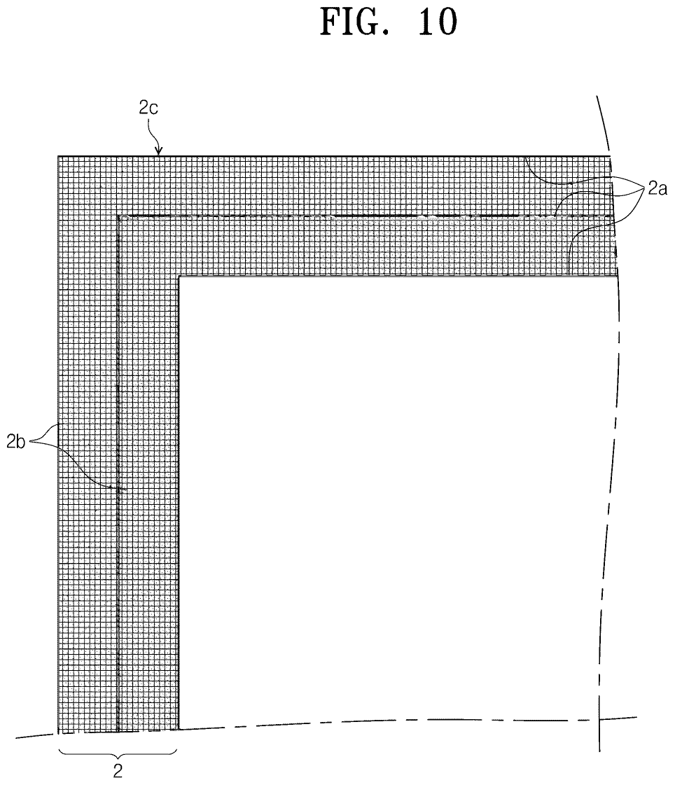

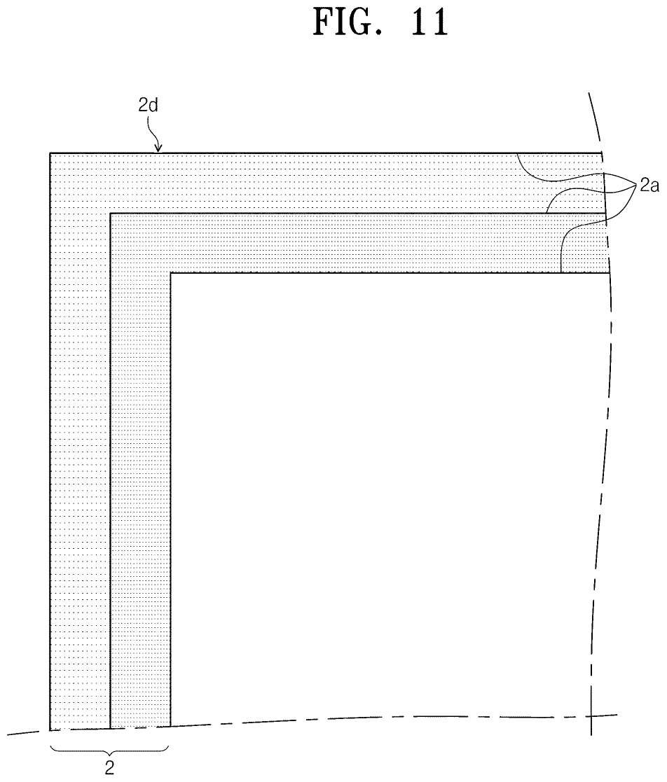

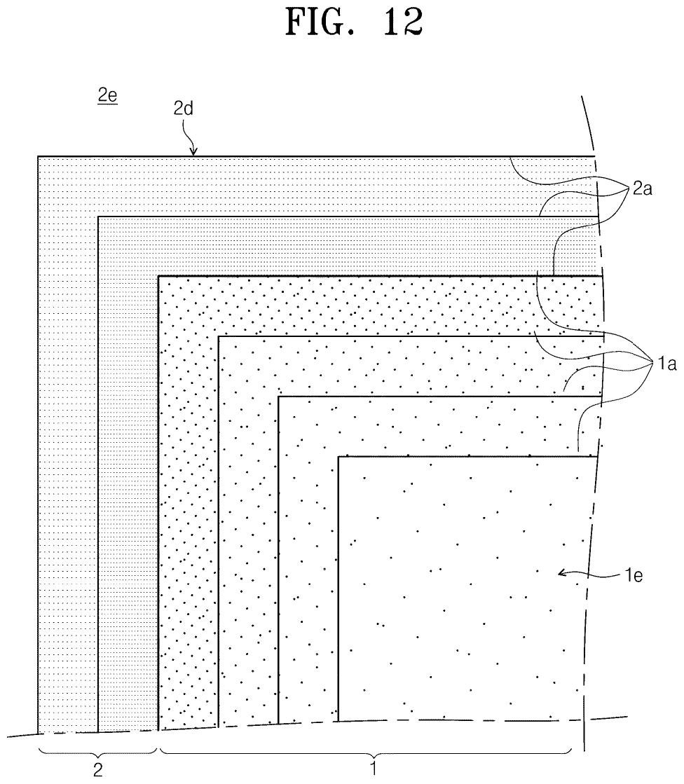

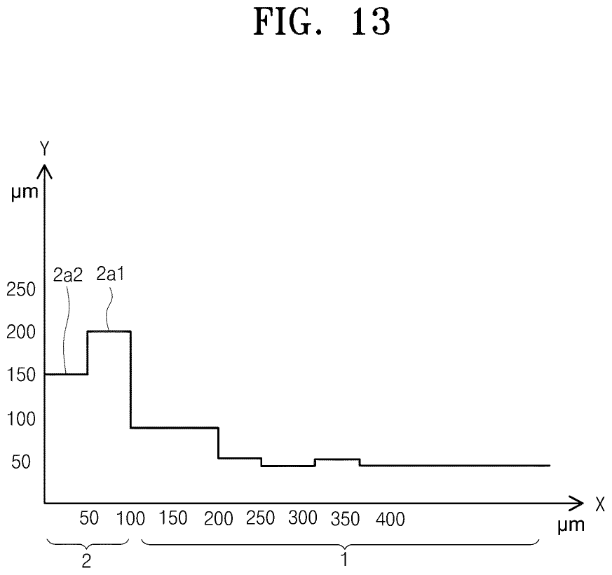

FIG. 1 is a diagram of a droplet processing device according to an exemplary embodiment of the present invention. FIG. 2 is a block diagram of a droplet profile generating terminal illustrated in FIG. 1. FIG. 3 is a diagram illustrating an example of a state in which a size of a general area illustrated in FIG. 2 is displayed on the droplet profile generating terminal. FIG. 4 is a diagram illustrating an example of a state in which brightness information is formed for each of the general areas illustrated in FIG. 3. FIG. 5 is a diagram illustrating an example of a state in which resolution information is formed for each of the general areas illustrated in FIG. 4. FIG. 6 is a diagram illustrating an example of halftoning each of the general areas illustrated in FIG. 5. FIG. 7 is a diagram illustrating an example of a state in which the general area halftoning image illustrated in FIG. 6 is randomly distributed in the form of dots to form a general area random print image. FIG. 8 is an example of a state in which a size of a target area illustrated in FIG. 2 is displayed on the droplet profile generating terminal. FIG. 9 is a diagram illustrating a state in which brightness information is formed for each of the target areas illustrated in FIG. 8. FIG. 10 is a diagram illustrating an example of a state in which resolution information is formed for each of the target areas illustrated in FIG. 9. FIG. 11 is a diagram illustrating an example of a state in which each of the target areas illustrated in FIG. 10 is halftoned. FIG. 12 is a diagram illustrating an example of a synthesized image of the general area halftoning image illustrated in FIG. 6 and the target area halftoning image illustrated in FIG. 11. FIG. 13 is a graph representing the distance between the target area and the general area as the x-axis and representing the thickness of the ink as the y-axis when printing is performed with the synthesized image illustrated in FIG. 12.

As illustrated in FIGS. 1 to 13, a droplet processing device according to an exemplary embodiment of the present invention includes a droplet profile generating terminal 10 and an inkjet system 20.

The droplet profile generating terminal 10 is a communication terminal device, such as a PC or a laptop computer, which generates a synthesized image 2e for printing droplets. In this case, the droplet profile generating terminal 10 is operated with an image generating program (not illustrated) installed to generate the synthesized image 2e, and the image generating program allows an operator to generate the synthesized image 2e by using a mouse and a keyboard that are input devices. Here, the image generating program may generate size information for an image by using graphical coordinate data on a two-dimensional plane, such as a CAD program, and may generate an image that includes brightness information, color information, and resolution information for each of the size information. Furthermore, the image generating program may generate the synthesized image 2e by changing the size information, the brightness information, the color information, and the resolution information of the generated image, and may change the color information, the brightness information, and the resolution information of the image in batches by applying various graphic filters. In this case, the image generating program may form an image in the form of dots by applying halftoning by using the brightness information and resolution information of the image when an entire area of the pixel value is formed of one color information, and form the formed image in a random print pattern that randomly distributes the number of images in the form of dots to which the halftoning has been applied within the unit plane region.

In one example of the droplet profile generating terminal 10 for generating the synthesized image 2e, the droplet profile generating terminal 10 includes a general area size setting unit 10a, a general area brightness setting unit 10b, a general area resolution setting unit 10c, and a general area halftoning setting unit 10d, a random print setting unit 10e, a target area size setting unit 10f, a target area brightness setting unit 10g, a target area resolution setting unit 10h, a target area halftoning setting unit 10i, a synthesized image generating unit 10j, and synthesized image transmitting unit 10k.

The general area size setting unit 10a sets general area size information 1a for a general area 1, as illustrated in FIG. 3. In the present exemplary embodiment, the general area size setting unit 10a may be set to a size in the form of a quadrangle plane, and may be implemented by a CAD program based on coordinates. Information used as a reference to set the size of the general area size setting unit 10a may be formed based on a semiconductor device graphic image based on a GDSII file in which a device and a circuit pattern for forming the cell are formed. Furthermore, in the general area size setting unit 10a, a plurality of general area size information 1a with different sizes may be formed, and in this case, the general area size information 1a with different sizes are equally spaced apart. The reason why the general area 1 is divided into a plurality of areas is to make a control to prevent the ink from agglomerating or unfilled by differing the thickness of the film for each of the plurality of general areas 1. As illustrated in the present exemplary embodiment, when ink is applied to the display substrate W, active area size information 1b may be formed on the inner side of the plurality of general area size information 1a. Here, the area corresponding to the active area size information 1b corresponds to the area in which the pixels emit light and displayed.

The general area brightness setting unit 10b receives an input of the general area size information 1a in conjunction with the general area size setting unit 10a, as illustrated in FIG. 4, and sets general area brightness information 1c for each area separated from the general area size information 1a. In this case, the general area brightness setting unit 10b sets the general area brightness information 1c in gray scale, so that the spraying density of the ink per unit plane may be adjusted based on the gray scale brightness information. For example, the brightness information for the gray scale of the active area 1b among the multiple divided general areas 1 may be set to 0xFE (decimal->254), which is the lowest brightness information when expressed in hexadecimal, and the brightness information of the general areas 1 formed on the outer side of the active area 1b may be set to darker brightness information than 0xFE (decimal->254) as the area move away from the active area.

The general area resolution setting unit 10c receives the general area brightness information 1c from the general area brightness setting unit 10b as illustrated in FIG. 5, and generates a pixelated general area image 1d by setting the general area resolution information for the general area size information 1a in a grid form. In this case, each pixel value formed in the general area image 1d may be set to the same size, or may be set to a different size for each area as needed to control the density of the ink dots described later.

The general area halftoning setting unit 10d receives an input of the general area image 1d in conjunction with the general area resolution setting unit 10c as illustrated in FIG. 6, and halftones the general area image 1d into the form of dots to generate a general area halftoning image 1e. In this case, the general area halftoning setting unit 10d form the dots to be denser as the value set in the general area brightness information 1c is darker. For example, the active area with brightness information of 0xFE (decimal->254) is printed with a lower density of dots after halftoning than another general area 1 with darker brightness information than 0xFE (decimal->254). Accordingly, when the printing is performed on the substrate W through the synthesized image 2e described below, more dots are formed in the general area 1 having darker brightness information than the active area 1b. Thus, the active area 1b is formed with a thin film having the smallest thickness than the thickness of the area excluding the active area 1b.

The random print setting unit 10e receives an input of the general area halftoning image 1e in conjunction with the general area halftoning setting unit 10d, as illustrated in FIG. 7, and randomly distributes at least a portion of the input general area halftoning image 1e in the form of dots to form a general area random print image 1f. Therefore, in the area where the general area halftoning image 1e is generated, the dots of the ink are composed of only a reference number of dots per unit plane, which prevents the dots from agglomerating when printing.

The target area size setting unit 10f sets target area size information 2a for a target area 2, as illustrated in FIG. 8, and the target area size information 2a may be set by the above-described CAD program. In the case of the present exemplary embodiment, the target area 2 corresponds to an edge area that is not displayed in the display substrate W, and accordingly, the target area size setting unit 10f sets the target area 2 to enclose the border of the general area 1, so that the ink is sprayed with a higher dot density in the target area 2 than the general area 1 described above and the target area 2 is formed with a higher thickness than the general area 1. In the present exemplary embodiment, the target area 2 is formed by dividing the target area 2 into a first target area 2al having a size that encloses the general area 1 and a second target area 2a2 enclosing the first target area 2al. The reason why the first target area 2al and the second target area 2a2 are set separately is to prevent unfilled areas from occurring due to surface tension by forming different thicknesses.

As illustrated in FIG. 9, the target area brightness setting unit 10g receives an input of the target area size information 2a in conjunction with the target area size setting unit 10f, and sets target area brightness information 2b for target area size information 2a. In this case, the target area brightness setting unit 10g sets the target area brightness information 2b to a gray scale, so that the spraying density of the ink per unit plane may be adjusted based on the gray scale brightness information. Furthermore, the target area brightness setting unit 10g forms the target area brightness information 2b with a darker brightness than the general area brightness information 1c, so that the number of dots may be configured with a higher density per unit plane during the halftoning described below. In the present exemplary embodiment, the brightness information of the first target area 2al is formed with darker brightness information than the second target area 2a2, so that the thickness of the first target area 2al is formed with a greater thickness than the thickness of the second target area 2a2 at the time of final printing.

As illustrated in FIG. 10, the target area resolution setting unit 10h receives an input of the target area brightness information 2b from the target area brightness setting unit 10g, and sets the target area resolution information for the target area size information 2a in the form of a grid to generate a pixelated target area image 2c. In this case, each of the pixel values formed in the target area image 2c is set to the same size or to a different size as needed, and may be set to the same size as the pixel value of the general area image 1d described above.

The target area halftoning setting unit 10i receives an input of the target area image 2c in conjunction with the target area resolution setting unit 10h, as illustrated in FIG. 11, and halftones the target area image 2c in the form of dots to generate a target area halftoning image 2d. In this case, the darker the value set in the general area brightness information 1c, the denser the dots are formed in the target area halftoning setting unit 10i. Here, since the first target area 2al has the darkest brightness information as described above, the highest density of dots per unit plane is formed. In this case, since the random printing described above is not applied to the target area halftoning image 2D, it is possible to perform printing beyond the thickness of the general area 1. For example, when the maximum thickness of the general area 1 where the random printing is performed is 100 μm, the printing may be performed on the target area 2 with a thickness of 200 μm in excess of 100 μm. In this way, dots with a higher density than that in the general area 1 are printed in the target area 2, allowing printing to proceed with a thickness that cannot be printed in the general area 1. In particular, up to 100% of the total amount of ink discharged of the inkjet system 20 is discharged to the target area 2 to increase the thickness of the thin film. As a result, the random print pattern is applied to the target area 2, so that the thin film may be formed with a thickness twice the thickness of the general area 1 in which the thin film is formed with the thickness corresponding to 50% of the total amount of ink discharged.

The synthesized image generating unit 10j receives an input of the general area halftoning image 1e from the general area halftoning setting unit 10d and receives an input of the target area halftoning image 2d from the target area halftoning setting unit 10i, as illustrated in FIG. 12. In this case, the synthesized image generating unit 10j formats the general area halftoning image 1e and the target area halftoning image 2d into one image to generate the synthesized image 2e, as illustrated in FIG. 12. Accordingly, the synthesized image 2e is formed in the form in which the target area halftoning image 2d surrounds the general area halftoning image 1e.

The synthesized image transmitting unit 10k receives an input of the synthesized image 2e in conjunction with the synthesized image generating unit 10j, and transmits the received synthesized image 2e to the inkjet system 20. Accordingly, the inkjet system 20 proceeds to print on the substrate W based on the information of the synthesized image 2e.

In this case, the inkjet system 20 is an apparatus for applying ink to a surface of the substrate W in an inkjet manner, and includes a base 100 made of steel, a stage 200 disposed on top of the base 100 and transferring the substrate W, a head assembly 300 having a plurality of inkjet heads disposed above the stage 200 and applying ink to a surface of the substrate W seated on the stage 200, and a head transfer part 400 supporting the head assembly 300 and transferring the head assembly 300. However, the present invention is not intended to limit the inkjet system 20 to the above examples, and it is of course understood that the inkjet system 20 may be implemented in various variations that receive an input of the synthesized images 2e and apply ink based on the synthesized images 2e.

Furthermore, the substrate W disposed on the inkjet system 20 is formed as a display substrate with a plurality of cells, and the synthesized image 2e is used to print the sealing layer in the form of a thin film for each cell formed on the display substrate. However, the present invention does not limit the use of the synthesized image 2e to being used on a display substrate, and it is a matter of course that the synthesized image 2e may be used on various substrates, such as display substrates, solar substrates, semiconductor substrates, and the like. Furthermore, it is a matter of course that the synthesized image 2e may be used to form various layers, such as an organic light emitting layer, an insulating layer, a conductive layer, or a sealing layer, on the above substrate and the like. As such, the synthesized image 2e may be used to form thickness layers for various purposes on various substrates by varying the settings of the target area 2 and the general area 1.

The following describes a droplet processing method by using the foregoing droplet processing device.

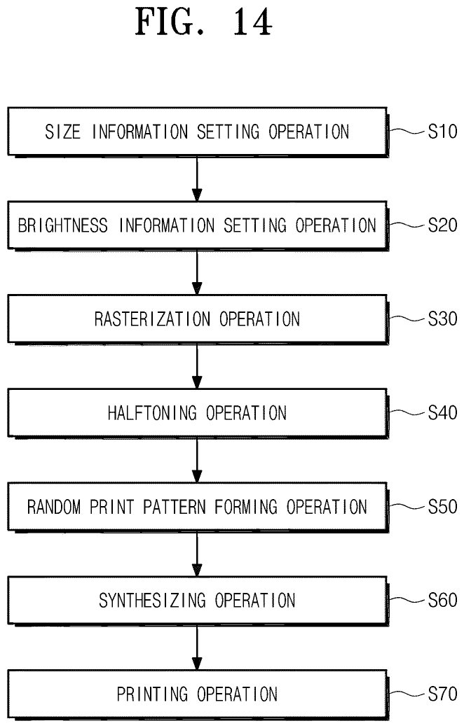

FIG. 14 is a flowchart of a droplet processing method according to an exemplary embodiment of the present invention.

Referring further to FIG. 14, a droplet processing method according to an exemplary embodiment of the present invention includes a size information setting operation S10, a brightness information setting operation S20, a rasterization operation S30, a halftoning operation S40, a random print pattern formation operation S50, a synthesis operation S60, and a printing operation S70.

First, in the size information setting operation S10, the general area size setting unit 10a sets general area size information 1a for a general area 1, and the target area size setting unit 10f sets target area size information 2a for a target area 2. In this case, in the size information setting operation S10, the target area 2 may be set to surround the border of the general area 1.

Next, in the brightness information setting operation S20, the general area brightness setting unit 10b sets general area brightness information 1c for the general area size information 1a, and the target area brightness setting unit 10g sets target area brightness information 2b for the target area size information 2a. In this case, in the brightness information setting operation S20, as described above, the general area brightness setting unit 10b sets the brightness information of the general area 1 to gray scale, and the target area brightness setting unit 10g sets the target area brightness information 2b to lower brightness than the general area brightness information 1c. The brightness information generated in the brightness information setting operation S20 is set by varying the number of dots per unit plane according to the brightness information when the halftoning operation S40 described later proceeds. Thus, by controlling the brightness information, the thickness of the film may be controlled by the density of the dots.

Next, in the rasterization operation S30, the general area resolution setting unit 10c sets general area resolution information for the general area size information 1a and generates a pixelated general area image 1d, and the target area resolution setting unit 10h sets target area resolution information for the target area size information 2a and generates a pixelated target area image 2c. In the present exemplary embodiment, the general area image 1d and the target area image 2c are formed with the same size of pixel values. However, the present invention is not limited to forming the same pixel value size of each of the general area image 1d and the target area image 2c, and the pixel value size of each of the general area image 1d and the target area image 2c may be set differently from each other as needed.

Next, in the halftoning operation S40, the general area halftoning setting unit 10d halftones the general area image 1d in the form of dots to generate a general area halftoning image 1e, and the target area halftoning setting unit 10i halftones the target area image 2c in the form of dots. Thus, the spraying position of the ink may be specified in the general area halftoning image 1e and the target area halftoning image 2d generated by the halftoning operation.

Next, in the random print pattern formation operation S50, at least a portion of the general area halftoning image 1e is randomly distributed in the form of dots. Thus, when the generalized halftoning image 1e is used, the dots are prevented agglomerating together during droplet printing as described above.

Next, in the synthesis operation S60, the general area halftoning image 1e and the target area halftoning image 2d are formatted into one image to generate a synthesized image 2e.

Next, in the printing operation S70, the synthesized image 2e is supplied to the inkjet system 20 to print the synthesized image 2e on the substrate. In this case, the target area halftoning image 2d in the synthesized image 2e is formed with darker brightness information than the general area halftoning image 1e while surrounding the general area halftoning image 1e, so the target area halftoning image 2d is formed with a thickness greater than the thickness of the area printed through the general area halftoning image 1e.

In this case, the random printing is not applied to the thickness of the thin film applied on the target area halftoning image 2d side, so printing may proceed in the state where the thickness of the thin film of the target area halftoning image 2d exceeds the limit value of the thickness of the thin film of the general area halftoning image 1e side on which the random printing is performed. In particular, since the random print pattern is not applied to the target area 2, the thickness of the thin film may be increased by discharging up to 100% of the total amount of ink discharged of the inkjet system 2. As a result, the random print pattern is applied to the target area 2, so that the thin film may be formed with a thickness twice the thickness of the general area 1 in which the thin film is formed with the thickness corresponding to 50% of the total amount of ink discharged. For example, by random printing, the print thickness of the target area halftoning image 2d may be increased to 200 μm, compared to the limit of 100 μm for the print thickness of the general area halftoning image 1e. Therefore, the thickness of the thin film sprayed on the side of the target area halftoning image 2d is formed at a greater thickness than the general area 1, so that the ink does not agglomerate due to surface tension and to prevent ink unfilled areas from being generated.

In this way, the droplet processing device and the droplet processing method according to the exemplary embodiment of the present invention may form a thin film in the form in which the ink does not agglomerate by adjusting the brightness information and resolution information of the general area 1 and the amount of dots distributed during random printing as needed, and form a thin film by adjusting the brightness information and resolution information of the target area 2 where random printing is not required, and discharging up to 100% of the amount of ink discharged.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description. Therefore, the spirit of the present invention should not be limited to the described exemplary embodiments, and it will be the that not only the claims to be described later, but also all modifications equivalent to the claims belong to the scope of the present invention.

1. A droplet processing device comprising:
a droplet profile generating terminal for generating a general area halftoning image to which a random print pattern is applied, generating a target area halftoning image to which the random print pattern is not applied, and synthesizing the general area halftoning image and the target area halftoning image to generate a synthesized image; and
an inkjet system for receiving an input of the synthesized image and spraying droplets onto a substrate based on dot locations present in the synthesized image.

2. The droplet processing device of claim 1, wherein the droplet profile generating terminal includes:
a general area size setting unit which sets the general area size information for a general area; and
a general area brightness setting unit which receives an input of the general area size information in conjunction with the general area size setting unit and sets general area brightness information for the general area size information.

3. The droplet processing device of claim 2, wherein the general area brightness setting unit sets the general area brightness information to gray scale.

4. The droplet processing device of claim 2, wherein the droplet profile generating terminal further includes a general area resolution setting unit which receives an input of the general area brightness information from the general area brightness setting unit, and sets general area resolution information for the general area size information to generate a pixelated general area image.

5. The droplet processing device of claim 4, wherein the droplet profile generating terminal further includes a general area halftoning setting unit which receives an input of the general area image in conjunction with the general area resolution setting unit, and halftones the general area image in the form of dots to generate a general area halftoning image.

6. The droplet processing device of claim 5, wherein the droplet profile generating terminal further includes a random print setting unit which receives an input of the general area halftoning image in conjunction with the general area halftoning setting unit, and randomly distributes at least one portion of the general area halftoning image in the form of dots to form a general area random print image.

7. The droplet processing device of claim 6, wherein the droplet profile generating terminal further includes a target area size setting unit which sets the target area size information for a target area.

8. The droplet processing device of claim 7, wherein the target area size setting unit sets the target area to surround a border of the general area.

9. The droplet processing device of claim 7, wherein the droplet profile generating terminal further includes a target area brightness setting unit which receives an input of the target area size information in conjunction with the target area size setting unit, and sets target area brightness information for the target area size information.

10. The droplet processing device of claim 9, wherein the target area brightness setting unit sets the target area brightness information to gray scale.

11. The droplet processing device of claim 9, wherein the target area brightness setting unit forms the target area brightness information to brightness lower than the general area brightness information.

12. The droplet processing device of claim 7, wherein the droplet profile generating terminal further includes a target area resolution setting unit which receives an input of the target area brightness information from the target area brightness setting unit, and sets target area resolution information for the target area size information to generate a pixelated target area image.

13. The droplet processing device of claim 12, wherein the droplet profile generating terminal further includes a target area halftoning setting unit which receives an input of the target area image in conjunction with the target area resolution setting unit, and generates a target area halftoning image by halftoning the target area image in the form of dots.

14. The droplet processing device of claim 13, wherein the droplet profile generating terminal further includes a synthesized image generating unit which receives an input of the general area halftoning image from the general area halftoning setting unit, receives an input of the target area halftoning image from the target area halftoning setting unit, and formats the general area halftoning image and the target area halftoning image into a single image to generate a synthesized image.

15. The droplet processing device of claim 14, wherein the droplet profile generating terminal further includes a synthesized image transmitting unit which receives an input of the synthesized image in conjunction with the synthesized image generating unit, and transmits the received synthesized image to an inkjet system.

16.-19. (canceled)

20. A droplet processing device comprising:
a droplet profile generating terminal including a general area size setting unit which sets general area size information for a general area, a general area brightness setting unit which receives an input of the general area size information in conjunction with the general area size setting unit, sets general area brightness information for the general area size information, and sets the general area brightness information to gray scale, a general area resolution setting unit which receives an input of the general area brightness information from the general area brightness setting unit, and sets general area resolution information for the general area size information to generate a pixelated general area image, a general area halftoning setting unit which receives an input of the general area image in conjunction with the general area resolution setting unit, and halftones the general area image in the form of dots to generate a general area halftoning image, a random print setting unit which receives an input of the general area halftoning image in conjunction with the general area halftoning setting unit, and randomly distributes at least one portion of the general area halftoning image in the form of dots to form a general area random print image, a target area size setting unit which sets the target area size information for a target area and sets the target area to surround a border of the general area, a target area brightness setting unit which receives an input of the target area size information in conjunction with the target area size setting unit, sets target area brightness information for the target area size information to lower brightness than the general area brightness information, and sets the target area brightness information to gray scale, a target area resolution setting unit which receives an input of the target area brightness information from the target area brightness setting unit, and sets target area resolution information for the target area size information to generate a pixelated target area image, a target area halftoning setting unit which receives an input of the target area image in conjunction with the target area resolution setting unit, and generates a target area halftoning image by halftoning the target area image in the form of dots, a synthesized image generating unit which receives an input of the general area halftoning image from the general area halftoning setting unit, receives an input of the target area halftoning image from the target area halftoning setting unit, and formats the general area halftoning image and the target area halftoning image into a single image to generate a synthesized image, and a synthesized image transmitting unit which receives an input of the synthesized image in conjunction with the synthesized image generating unit, and transmits the received synthesized image to an inkjet system; and
an inkjet system for receiving an input of the synthesized image and spraying droplets onto a substrate based on dot locations present in the synthesized image.
